(19) United States
(12) Patent Application Publication
(10) Pub. No.: US 2025/0273467 A1
(43) Pub. Date: Aug. 28, 2025

(54) LASER HEAT TREATMENT METHOD AND MANUFACTURING METHOD OF ELECTRONIC DEVICE USING THE SAME

(71) Applicant: RNR LAB INC., Gyeonggi-do (KR)

(72) Inventors: Jeong Do Ryu, Seoul (KR); Sung Ho Kang, Gyeonggi-do (KR); Joo Hyun Cho, Gyeonggi-do (KR); Sung Hoon Ryu, Gangwon-do (KR)

(21) Appl. No.: 19/056,639

(22) Filed: Feb. 18, 2025

(30) Foreign Application Priority Data
Feb. 28, 2024 (KR) 10-2024-0030156

(51) Int. Cl. H01L 21/268; B23K 26/082; B23K 101/40; H01L 21/263

(52) U.S. Cl. CPC H01L 21/268; B23K 26/0821; H01L 21/2636; B23K 2101/40

(57) ABSTRACT

The present disclosure provides a laser heat treatment method including a step for providing a substrate structure including a target substance layer to be heat treated, a step for forming a capping substance layer having a multi-layer structure including a non-conductive substance layer and a conductive substance layer on the target substance layer, and a step for performing heat treatment on the target substance layer by irradiating a laser to the capping substance layer.

### CROSS-REFERENCE TO RELATED APPLICATION

This application claims priority of Korean Patent Application No. 10-2024-0030156, filed on Feb. 28, 2024, in the KIPO (Korean Intellectual Property Office), the disclosure of which is incorporated herein entirely by reference.

### BACKGROUND OF THE INVENTION

### Field of the Invention

The present invention relates to a heat treatment method for a treatment target and a manufacturing method of a device using the same, and more specifically, to a laser heat treatment method and a manufacturing method of an electronic device using the same.

### Description of the Related Art

The semiconductor devices/electronic devices may be manufactured through multiple processes. The processes for manufacturing semiconductor devices/electronic devices may include, for example, a thin film deposition process, a photolithography process, an etching process, an ion implantation process, a heat treatment (i.e., annealing) process, etc. Among these, the heat treatment process may be a process for improving and securing the characteristics of a device by stabilizing, activating, melting a substrate or a thin film formed on the substrate, or removing seam defects within the thin film. The heat treatment (annealing) process may include a laser heat treatment process, a rapid thermal process (RTP), etc.

As the laser heat treatment process may mainly perform heat treatment on the surface of the substrate or adjacent areas by using a laser, there are advantages that the impact on other processes is reduced, and temperature increase and control are relatively easy. However, as the integration of semiconductor devices/electronic devices improves, the size of unit devices continues to decrease, and the processes become more advanced, it is difficult to control heat distribution and heat transfer during laser heat treatment, it is not easy to control cooling behavior or cooling speed, and the problems such as property changes/deterioration and substance damage/consumption due to unwanted reactions between substances may occur. As a result, the problems such as deterioration of the characteristics of the device and increase in the defect rate may occur.

### SUMMARY OF THE INVENTION

The technological object to be achieved by the present invention is to provide a laser heat treatment method capable of easily controlling heat distribution and heat transfer characteristics, and easily adjusting cooling behavior and cooling speed when performing heat treatment on a predetermined target by using a laser.

Furthermore, the technological object to be achieved by the present invention is to provide a laser heat treatment method which may prevent the problems such as property change/deterioration and substance damage/consumption due to unwanted reactions between substances while securing excellent heat treatment characteristics when performing heat treatment on a predetermined target by using a laser.

Furthermore, the technological object to be achieved by the present invention is to provide a manufacturing method of an electronic device (a semiconductor device) to which the above-mentioned laser heat treatment method is applied.

The technological objects to be achieved by the present invention are not limited to the objects mentioned above, and other objects which are not mentioned may be understood by those skilled in the art from the description below.

According to one embodiment of the present invention, there is provided a laser heat treatment method comprising: a step for providing a substrate structure including a target substance layer to be heat treated; a step for forming a capping substance layer having a multi-layer structure including a non-conductive substance layer and a conductive substance layer on the target substance layer; and a step for performing heat treatment on the target substance layer by irradiating a laser to the capping substance layer.

The non-conductive substance layer and the conductive substance layer may be sequentially arranged on the target substance layer.

The conductive substance layer and the non-conductive substance layer may be sequentially arranged on the target substance layer.

The capping substance layer may further include a reaction-suppressing layer disposed between the target substance layer and the conductive substance layer when the conductive substance layer and the non-conductive substance layer are sequentially disposed on the target substance layer, and the reaction-suppressing layer may be configured to suppress substance diffusion and reaction between the target substance layer and the conductive substance layer.

The reaction suppression layer may include a non-conductive substance.

The reaction suppression layer may have a thickness of about 0.5 nm or more.

The non-conductive substance layer may include an inorganic dielectric substance.

The non-conductive substance layer may have a thickness in the range of about 0.5 to 1000 nm when the non-conductive substance layer and the conductive substance layer are sequentially arranged on the target substance layer.

The non-conductive substance layer may have a thickness in the range of about 0.5 to 1000 nm when the conductive substance layer and the non-conductive substance layer are sequentially arranged on the target substance layer.

The conductive substance layer may include a metallic substance.

The conductive substance layer may have a thickness in a range of about 0.5 to 1000 nm.

The target substance layer may have a single-layer structure or a multi-layer structure including at least two different substance layers.

The target substance layer may include at least any one of a semiconductor layer and an insulator layer, and the laser heat treatment may be performed to change crystallinity, physical properties, or film quality of at least any one of the semiconductor layer and the insulator layer.

The laser heat treatment method may further include a step for removing at least a portion of the capping substance layer after the step for performing heat treatment on the target substance layer.

The laser may be irradiated to the capping substance layer in a scanning manner.

The laser may be irradiated by using a polygon scanner or a galvanometer scanner.

The scanning speed of the above laser may be about 1 m/s or more.

The laser may be irradiated to the capping substance layer in a stepper manner.

The laser may have a wavelength of about 0.01 μm to 11 μm.

According to another embodiment of the present invention, there is provided a manufacturing method of an electronic device comprising: a step for performing heat treatment on a target substance layer by using the aforementioned laser heat treatment method; and a step for forming an electronic device including the heat-treated target substance layer.

According to embodiments of the present invention, it is possible to implement a laser heat treatment method in which heat distribution and heat transfer characteristics may be easily controlled and cooling behavior and cooling speed may be easily adjusted when performing heat treatment on a predetermined target by using a laser. Furthermore, according to embodiments of the present invention, when performing heat treatment on a predetermined target by using a laser, it is possible to implement a laser heat treatment method which may prevent the problems such as property changes/deterioration and substance damage/consumption due to unwanted reactions between substances while securing excellent heat treatment characteristics.

When applying the laser heat treatment method according to embodiments of the present invention, it is possible to manufacture electronic devices (semiconductor devices) having excellent performance and uniformity, and to reduce the defect rate and to improve the yield.

However, the effects of the present invention are not limited to the above effects, and may be variously expanded within a scope which does not depart from the technological spirit and scope of the present invention.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1A and FIG. 1B are cross-sectional views illustrating a laser heat treatment method according to one embodiment of the present invention.

FIG. 2A and FIG. 2B are cross-sectional views illustrating a laser heat treatment method according to another embodiment of the present invention.

FIG. 3A and FIG. 3B are cross-sectional views illustrating a laser heat treatment method according to another embodiment of the present invention.

FIG. 4 to FIG. 6 are cross-sectional views for explaining a laser heat treatment method according to another embodiment of the present invention. FIG. 4 is an embodiment modified based on FIG. 1B,

FIG. 5 is an embodiment modified based on FIG. 2B, and

FIG. 6 is an embodiment modified based on FIG. 3B.

FIG. 7 is a cross-sectional view for explaining a laser heat treatment method according to another embodiment of the present invention.

FIG. 8 is a cross-sectional view for explaining a laser heat treatment method according to a comparative example.

FIG. 9 is a cross-sectional view for explaining heat flow characteristics which may appear in a laser heat treatment method according to an embodiment of the present invention.

FIG. 10 is a cross-sectional view for explaining a laser heat treatment method according to an embodiment of the present invention.

FIG. 11 is a drawing schematically illustrating a polygon scanner which may be applied to a laser heat treatment method according to an embodiment of the present invention.

FIG. 12 is a drawing schematically illustrating a galvanometer scanner which may be applied to a laser heat treatment method according to an embodiment of the present invention.

FIG. 13 is a perspective view for explaining a manufacturing method of an electronic device using a laser heat treatment method according to an embodiment of the present invention.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed “on” a substrate or other layer refers to a layer formed directly on top of the substrate or other layer or to an intermediate layer or intermediate layers formed on the substrate or other layer. It will also be understood by those skilled in the art that structures or shapes that are “adjacent” to other structures or shapes may have portions that overlap or are disposed below the adjacent features.

In this specification, the relative terms, such as “below”, “above”, “upper”, “lower”, “horizontal”, and “vertical”, may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

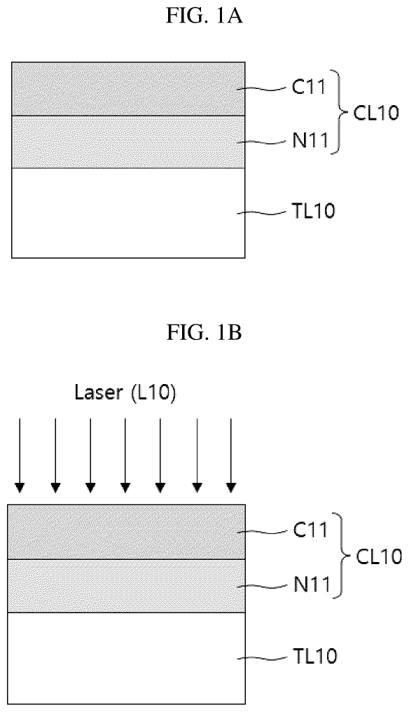

FIG. 1A and FIG. 1B are cross-sectional views illustrating a laser heat treatment method according to one embodiment of the present invention.

Referring to FIG. 1A, a substrate structure including a target substance layer TL10 to be heat treated may be prepared. The target substance layer TL10 may include, for example, a semiconductor layer or an insulator layer. The target substance layer TL10 may be a substance layer used to manufacture a predetermined electronic device (a semiconductor device). That is, the target substance layer TL10 may be a component of the electronic device (semiconductor device). The term, ‘layer’ in the target substance layer TL10 may be interpreted broadly. Here, ‘layer’ may be a continuous layer, a patterned layer, a plug-shaped layer, etc., or may mean a portion of a substrate (a substrate structure).

The substrate structure may include a semiconductor substrate or an insulating substrate, or in some cases, a conductive substrate. Furthermore, the substrate structure may further include an element unit including a predetermined thin film or thin films formed on the substrate (a base substrate). The semiconductor substrate may include at least one of various semiconductor substances, such as, but not limited to, Si, Ge, SiGe, SiC, GaN, GaAs, etc. The thin film may include at least one of a semiconductor thin film, an insulating thin film, and a conductive thin film. The semiconductor thin film may comprise various semiconductor substances including amorphous silicon and polycrystalline silicon. The insulating thin film (an insulator layer) may be composed of a ceramic substance. The insulating thin film may include a high-k substance having a higher dielectric constant than that of silicon oxide, silicon nitride, silicon oxynitride, or silicon nitride. The conductive thin film may include, for example, at least one of a metal and a metal compound. As a non-limiting example, the element unit may include a switching element such as a transistor or a diode, or a memory element such as a storage node, a capacitor, or a resistance change layer. Furthermore, the substrate structure may include a wafer or have a wafer shape.

A capping substance layer CL10 having a multi-layer structure may be formed on a target substance layer TL10. The capping substance layer CL10 may have a multi-layer structure including a non-conductive substance layer N11 and a conductive substance layer C11. In the present embodiment, the non-conductive substance layer N11 and the conductive substance layer C11 may be sequentially arranged on the target substance layer TL10. The non-conductive substance layer N11 may be a non-conductive layer in terms of electrical conductivity. The conductive substance layer C11 may be a conductive layer in terms of electrical conductivity. The non-conductive substance layer N11 may be referred to as a ‘first capping substance layer’, and the conductive substance layer C11 may be referred to as a ‘second capping substance layer’. The non-conductive substance layer N11 may be arranged between the target substance layer TL10 and the conductive substance layer C11. The non-conductive substance layer N11 may be in direct contact with the target substance layer TL10, and the conductive substance layer C11 may be in direct contact with the non-conductive substance layer N11. The conductive substance layer C11 may be separated from the target substance layer TL10 by a non-conductive substance layer N11. The capping substance layer CL10 may be formed to entirely cover the target substance layer TL10.

The conductive substance layer C11 may be a heating layer. The conductive substance layer C11 may include a metallic substance. The conductive substance layer C11 may include at least one of a metal and a metal compound. The conductive substance layer C11 may be formed of at least one of a metal and a metal compound. As a non-limiting example, the conductive substance layer C11 may include at least one of TiN, Ti, TiSi, Ta, TaN, Co, CoSi, Ni, NiSi, Ru, W, WSi, Cu, Re, Mo, Nb, and Cr. It may be preferable that the conductive substance layer C11 has a thickness of about 0.5 nm to 1000 nm to improve its function, but the present embodiment is not limited thereto, and in some cases, the appropriate thickness of the conductive substance layer C11 may vary. The conductive substance layer C11 may have a relatively high absorption rate for laser, and may play a role in transferring or trapping heat toward the target substance layer TL10. In this regard, the conductive substance layer C11 may be referred to as a ‘laser absorption layer (high absorption layer)’ or a ‘heat transfer layer’.

The non-conductive substance layer N11 may play a role to suppress or prevent reaction and substance diffusion between the target substance layer TL10 and the conductive substance layer C11. In this respect, the non-conductive substance layer N11 may be called a reaction suppression layer or a diffusion barrier layer. The non-conductive substance layer N11 may be an electrical insulating layer. The non-conductive substance layer N11 may include, for example, an inorganic dielectric substance (an inorganic insulating substance) or be formed of an inorganic dielectric substance (an inorganic insulating substance). As a non-limiting example, the non-conductive substance layer N11 may include at least one of silicon oxide (e.g., SiO₂), silicon nitride (e.g., Si₃N₄), silicon nitride, and a high-k substance. The high-k substance may be a substance having a higher dielectric constant than silicon nitride. As a non-limiting example, the high-k substance may include hafnium oxide (e.g., HfO₂), zirconium oxide (e.g., ZrO₂), and the like. However, the specific substance of the non-conductive substance layer N11 is not limited to the above-described, and may vary depending on the case. The thermal conductivity of the non-conductive substance layer N11 may be lower than the thermal conductivity of the conductive substance layer C11.

It may be desirable for the non-conductive substance layer N11 to have a thickness of about 0.5 nm or more to improve its function. If the thickness of the non-conductive substance layer N11 is too thin, that is, less than about 0.5 nm, the effect to suppress substance diffusion and reaction may be reduced. If the thickness of the non-conductive substance layer N11 is too thick, that is exceeds about 1000 nm, the effect to transfer heat from the conductive substance layer C11 to the target substance layer TL10 may be reduced. Therefore, it may be desirable for the non-conductive substance layer N11 to have a thickness in the range of about 0.5 to 1000 nm. However, the present embodiment is not limited thereto, and the appropriate thickness of the non-conductive substance layer N11 may vary depending on the case.

Referring to FIG. 1B, a heat treatment (i.e., annealing) may be performed on a target substance layer TL10 by irradiating a laser L10 onto a capping substance layer CL10. The laser L10 may be irradiated toward the capping substance layer CL10 from a space (a free space) above the capping substance layer CL10. The laser L10 may be a laser beam. The conductive substance layer C11 of the capping substance layer CL10 may be heated by irradiation of the laser L10, and the heat generated in the conductive substance layer C11 may be transferred to the target substance layer TL10. As a result of it, the target substance layer TL10 may be heat-treated. Therefore, the target substance layer TL10 may be heat-treated in an indirect heating manner. The heat generated in the conductive substance layer C11 may be transferred to the target substance layer TL10 through the non-conductive substance layer N11.

When the target substance layer TL10 includes a semiconductor layer or an insulator layer, a heat treatment using a laser (laser beam) may be performed to change the crystallinity, physical properties, or film quality of the semiconductor layer or the insulator layer. As a non-limiting example, the heat treatment using the laser may be performed for crystallization of an amorphous semiconductor (e.g., amorphous silicon), for removing defects such as a seam in a thin film, for activating a doped region, for stabilizing a substrate or a thin film, or for changing the physical properties of a substrate or a thin film. Furthermore, the heat treatment using the laser may be performed for various purposes.

The laser L10 used in the embodiment of the present invention may be, for example, one of ultraviolet ray, visible ray, infrared ray, and microwave. As a non-limiting example, the laser L10 may be a laser (laser beam) generated from any one of a YAG (yttrium aluminum garnet) laser generating device, a CO₂ laser generating device, a diode laser generating device, and a fiber laser generating device. The wavelength of the laser L10 may be, for example, about 0.01 μm to about 11 μm. However, a specific type and a wavelength range of the laser L10 are exemplary and may vary depending on various cases. Furthermore, in an embodiment of the present invention, the target substance layer TL10 may have an initial temperature of, for example, about 550° C. or less, and the heating temperature of the target substance layer TL10 caused by irradiation with the laser L10 may be, for example, in a range of about 200 to 3000° C. before performing heat treatment using the laser L10. When using a room temperature heater or a low temperature heater, the target substance layer TL10 may have a low initial temperature and may be heated by laser irradiation. However, the above temperature conditions are exemplary and may vary depending on various cases.

Thereafter, if necessary, a step for removing at least a portion of the capping substance layer CL10 may be further performed. The step of removing at least a portion of the capping substance layer CL10 may be referred to as a de-capping step. At least a portion of the capping substance layer CL10 may be removed in various ways, such as chemical etching or physical etching. The conductive substance layer C11 may be removed, and then the non-conductive substance layer N11 may be removed. When both of the conductive substance layer C11 and the non-conductive substance layer N11 are removed, the conductive substance layer C11 and the non-conductive substance layer N11 may not be used at all as components of an electronic device (semiconductor device). However, in some cases, after removing the conductive substance layer C11, at least a portion of the non-conductive substance layer N11 may remain.

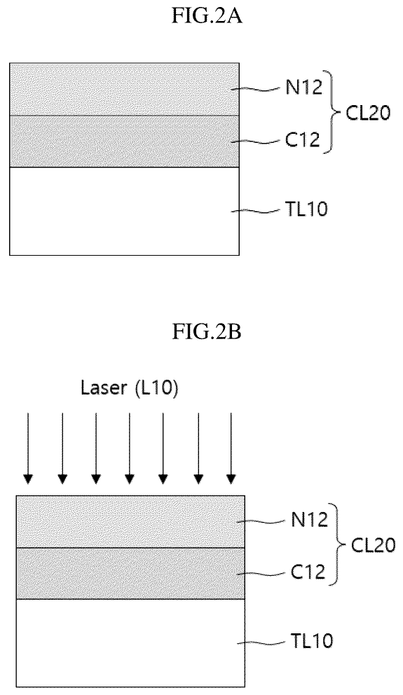

FIG. 2A and FIG. 2B are cross-sectional views illustrating a laser heat treatment method according to another embodiment of the present invention.

Referring to FIG. 2A, a substrate structure including a target substance layer TL10 may be prepared. The target substance layer TL10 and the substrate structure including the target substance layer TL10 may be the same as or similar to that described above in FIG. 1A.

A capping substance layer CL20 having a multi-layer structure may be formed on a target substance layer TL10. The capping substance layer CL20 may have a multi-layer structure including a conductive substance layer C12 and a non-conductive substance layer N12. In the present embodiment, the conductive substance layer C12 and the non-conductive substance layer N12 may be sequentially arranged on the target substance layer TL10. The conductive substance layer C12 may be a conductive layer in terms of electrical conductivity. The non-conductive substance layer N12 may be a non-conductive layer in terms of electrical conductivity. The conductive substance layer C12 may be referred to as a ‘first capping substance layer’, and the non-conductive substance layer N12 may be referred to as a ‘second capping substance layer’. The conductive substance layer C12 may be arranged between the target substance layer TL10 and the non-conductive substance layer N12. The conductive substance layer C12 may be in direct contact with the target substance layer TL10, and the non-conductive substance layer N12 may be in direct contact with the conductive substance layer C12. The non-conductive substance layer N12 may be separated from the target substance layer TL10 by the conductive substance layer C12.

The conductive substance layer C12 may be a heating layer. The conductive substance layer C12 may include a metallic substance. The conductive substance layer C12 may include at least one of a metal and a metal compound. The conductive substance layer C12 may be formed of at least one of a metal and a metal compound. As a non-limiting example, the conductive substance layer C12 may include at least any one of TiN, Ti, TiSi, Ta, TaN, Co, CoSi, Ni, NiSi, Ru, W, WSi, Cu, Re, Mo, Nb, and Cr. It may be preferable that the conductive substance layer C12 has a thickness of about 0.5 nm to 1000 nm to improve its function, but the present embodiment is not limited thereto, and the appropriate thickness of the conductive substance layer C12 may vary depending on many cases. The conductive substance layer C12 may have a relatively high absorption rate for laser, and may play a role in transferring or trapping heat toward the target substance layer TL10.

The non-conductive substance layer N12 may have lower thermal conductivity than that of the conductive substance layer C12. It may be desirable that the thermal conductivity of the non-conductive substance layer N12 is relatively low. The non-conductive substance layer N12 may be arranged on the uppermost part of the capping substance layer CL20. A conductive substance layer C12 having high heat absorption rate may be arranged on a lower surface of the non-conductive substance layer N12. The non-conductive substance layer N12 may effectively suppress heat generated in the conductive substance layer C12 by a laser from being released into the free space above the non-conductive substance layer N12. Therefore, during laser heat treatment, the speed at which heat is cooled through radiation (thermal radiation), convection (thermal convection), and conduction (thermal conduction) toward the top of the capping substance layer CL20 may be reduced by the non-conductive substance layer N12. In this regard, during laser heat treatment, heat transfer may be more effectively performed in the lateral direction in the conductive substance layer C12, and the problem such as heat distribution imbalance in the conductive substance layer C12 may be resolved. Furthermore, the non-conductive substance layer N12 may play a role to minimize changes in the conductive substance layer C12.

The non-conductive substance layer N12 may be an electrically insulating layer. The non-conductive substance layer N12 may include, for example, an inorganic dielectric substance (an inorganic insulating substance) or may be formed of an inorganic dielectric substance (an inorganic insulating substance). As a non-limiting example, the non-conductive substance layer N12 may include at least any one of silicon oxide (ex SiO₂), silicon nitride (ex Si₃N₄), silicon nitride, and a high-k substance. The high-k dielectric substance may be a substance having a higher dielectric constant than that of a silicon nitride. The high-k dielectric substance may include, but is not limited to, hafnium oxide (ex, HfO₂), zirconium oxide (ex, ZrO₂), etc. However, a specific substance of the non-conductive substance layer N12 is not limited to the above descriptions and may vary depending on the cases.

It may be desirable for the non-conductive substance layer N12 to have a thickness of about 0.5 nm to 1000 nm to improve its function and enhance process efficiency, etc. If the thickness of the non-conductive substance layer N12 is too thin, that is, less than about 0.5 nm, the effect to suppress heat release and to control cooling speed may be reduced. If the thickness of the non-conductive substance layer N12 is too thick, that is, exceeding about 1000 nm, the process efficiency may be reduced or the laser transmission efficiency to the conductive substance layer C12 may be somewhat reduced. Therefore, it may be desirable for the non-conductive substance layer N12 to have a thickness of about 0.5 nm to 1000 nm. However, the present embodiment is not limited thereto, and depending on the cases, the appropriate thickness of the non-conductive substance layer N12 may be changed.

Referring to FIG. 2B, a heat treatment (i.e., annealing) may be performed on a target substance layer TL10 by irradiating a laser L10 onto a capping substance layer CL20. The laser L10 may be irradiated toward the capping substance layer CL20 from a space (a free space) above the capping substance layer CL20. The conductive substance layer C12 of the capping substance layer CL20 may be heated by irradiation of the laser L10, and the heat generated in the conductive substance layer C12 may be transferred to the target substance layer TL10, and as a result, the target substance layer TL10 may be heat-treated. The target substance layer TL10 may be heat-treated by an indirect heating method.

The non-conductive substance layer N12 may effectively suppress heat generated in the conductive substance layer C12 by the laser L10 from being emitted into the free space above the non-conductive substance layer N12. Therefore, during laser heat treatment, the speed at which heat is cooled through radiation (thermal radiation), convection (thermal convection), and conduction (thermal conduction) to the upper part of the capping substance layer CL20 may be reduced by the non-conductive substance layer N12. In this regard, during laser heat treatment, heat transfer may be more effectively achieved to a lateral direction in the conductive substance layer C12, and the problem such as heat distribution imbalance in the conductive substance layer C12 may be solved.

The target substance layer TL10 may be patterned, for example, in a predetermined shape, or may have different densities (layer densities) or different thicknesses depending on the regions. In this case, heat absorption characteristics, heat reflection characteristics, and the like which are generated in the target substance layer TL10 may be different depending for each the region. This may cause a problem in which heat distribution becomes unbalanced within the target substance layer TL10 and the conductive substance layer C12. However, when a non-conductive substance layer N12 is arranged on a conductive substance layer C12, the non-conductive substance layer N12 suppresses heat from being released to the upper portion of the capping substance layer CL20, thereby reducing the cooling rate and increasing the uniformity of heat. Therefore, the problem such as heat distribution imbalance between the conductive substance layer C12 and the target substance layer TL10 may be effectively prevented.

Thereafter, if necessary, a step for removing at least a portion of the capping substance layer CL20 may be further performed. At least a portion of the capping substance layer CL20 may be removed in various ways, such as chemical etching or physical etching. The non-conductive substance layer N12 may be removed, and then the conductive substance layer C12 may be removed. Both of the non-conductive substance layer N12 and the conductive substance layer C12 may be removed. However, in some cases, at least a portion of the capping substance layer CL20 may be left without being removed.

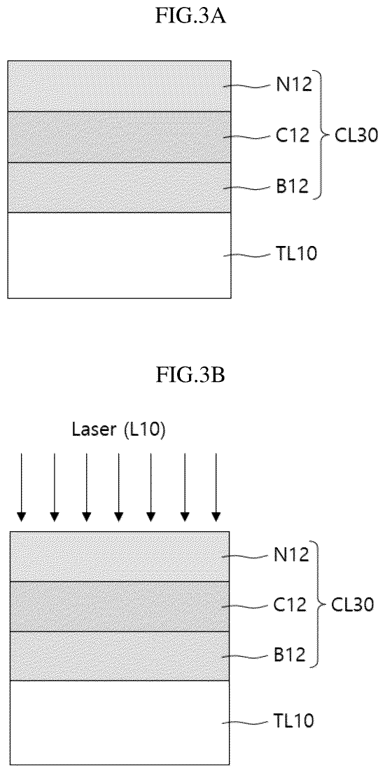

FIG. 3A and FIG. 3B are cross-sectional views illustrating a laser heat treatment method according to another embodiment of the present invention. This embodiment is a method which is modified from the embodiment of FIG. 2A and FIG. 2B.

Referring to FIG. 3A, a substrate structure including a target substance layer TL10 may be prepared. The target substance layer TL10 and the substrate structure including the target substance layer TL10 may be the same as or similar to that described above in FIG. 1A.

A capping substance layer CL30 having a multi-layer structure may be formed on a target substance layer TL10. The capping substance layer CL30 may include a conductive substance layer C12 and a non-conductive substance layer N12. Furthermore, the capping substance layer CL30 may further include a reaction suppression layer B12. In the present embodiment, the reaction suppression layer B12, the conductive substance layer C12, and the non-conductive substance layer N12 may be sequentially arranged on the target substance layer TL10. The reaction suppression layer B12 may be referred to as a ‘first capping substance layer’, the conductive substance layer C12 may be referred to as a ‘second capping substance layer’, and the non-conductive substance layer N12 may be referred to as a ‘third capping substance layer’. Alternatively, the conductive substance layer C12 may be referred to as a ‘first capping substance layer’, the non-conductive substance layer N12 may be referred to as a ‘second capping substance layer’, and the reaction suppression layer B12 may be referred to as a ‘third capping substance layer’. Furthermore, in some cases, the conductive substance layer C12 and the non-conductive substance layer N12 may be considered to constitute a single capping substance layer, and the reaction-suppressing layer B12 may be considered to be a separate substance layer from the capping substance layer.

The reaction suppression layer B12 may be disposed between the target substance layer TL10 and the conductive substance layer C12. The conductive substance layer C12 may be disposed between the reaction suppression layer B12 and the non-conductive substance layer N12. The reaction suppression layer B12 may be in direct contact with the target substance layer TL10, the conductive substance layer C12 may be in direct contact with the reaction suppression layer B12, and the non-conductive substance layer N12 may be in direct contact with the conductive substance layer C12. The conductive substance layer C12 may be separated from the target substance layer TL10 by the reaction suppression layer B12, and the non-conductive substance layer N12 may be separated from the reaction suppression layer B12 by the conductive substance layer C12.

The reaction suppression layer B12 may be configured to suppress substance diffusion and reaction between the target substance layer TL10 and the conductive substance layer C12. The reaction suppression layer B12 may be referred to as a type of diffusion barrier layer. The reaction suppression layer B12 may include a non-conductive substance. The reaction suppression layer B12 may be an electrical insulating layer. The reaction suppression layer B12 may include, for example, an inorganic dielectric substance (inorganic insulating substance) or may be formed of an inorganic dielectric substance (inorganic insulating substance). As a non-limiting example, the reaction suppression layer B12 may include at least any one of silicon oxide (e.g., SiO₂), silicon nitride (e.g., Si₃N₄), silicon nitride, and a high-k substance. The high-k substance may be a substance having a higher dielectric constant than that of a silicon nitride. The high-dielectric substance may include, but is not limited to, hafnium oxide (e.g., HfO₂), zirconium oxide (e.g., ZrO₂), etc. However, a specific substance of the reaction-suppressing layer B12 is not limited to the above description, and may vary depending on the cases. The thermal conductivity of the reaction-suppressing layer B12 may be lower than that of the conductive substance layer C12.

It may be desirable that the reaction suppression layer B12 has a thickness of about 0.5 nm to 1000 nm to improve its function. If the thickness of the reaction suppression layer B12 is too thin, that is, less than about 0.5 nm, the effect to suppress substance diffusion and reaction may be reduced. If the thickness of the reaction suppression layer B12 is too thick, that is, exceeds about 1000 nm, the effect to transfer heat from the conductive substance layer C12 to the target substance layer TL10 may be reduced. Therefore, it may be desirable that the reaction suppression layer B12 has a thickness of about 0.5 nm to 1000 nm. However, the present embodiment is not limited thereto, and the appropriate thickness of the reaction suppression layer B12 may vary depending on the cases.

Referring to FIG. 3B, a heat treatment (i.e., annealing) may be performed on a target substance layer TL10 by irradiating a laser L10 onto the capping substance layer CL30. The laser L10 may be irradiated toward the capping substance layer CL30 from the space (a free space) above the capping substance layer CL30. The conductive substance layer C12 of the capping substance layer CL30 may be heated by irradiation of the laser L10, and the heat generated in the conductive substance layer C12 may be transferred to the target substance layer TL10, and as a result, the target substance layer TL10 may be heat-treated. The target substance layer TL10 may be heat-treated according to an indirect heating method. The non-conductive substance layer N12 may effectively suppress a phenomenon that the heat in the conductive substance layer C12 generated by the laser L10 is emitted into the free space above the non-conductive substance layer N12.

Thereafter, if necessary, a step for removing at least a portion of the capping substance layer CL30 may be further performed. At least a portion of the capping substance layer CL30 may be removed in various ways, such as chemical etching or physical etching. The non-conductive substance layer N12, the conductive substance layer C12, and the reaction suppression layer B12 may be sequentially removed. The non-conductive substance layer N12, the conductive substance layer C12, and the reaction suppression layer B12 may all be removed. However, in some cases, at least a portion of the capping substance layer CL30 may be left without being removed. As a non-limiting example, at least a portion of the reaction-suppressing layer B12 may be left after the non-conductive substance layer N12 and the conductive substance layer C12 are removed.

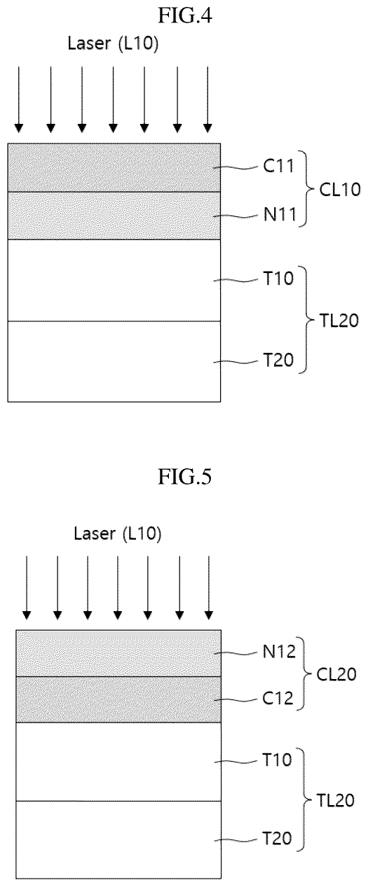

In the embodiments of FIGS. 1A and 1B, 2A and 2B, and 3A and 3B, the target substance layer TL10 is illustrated as a single-layer structure, but the target substance layer TL10 may have a multi-layer structure including at least two different substance layers. The target substance layer TL10 may have a multi-layer structure of two or more layers. The cases where the target substance layer has a multi-layer structure are illustrated in FIGS. 4 to 7.

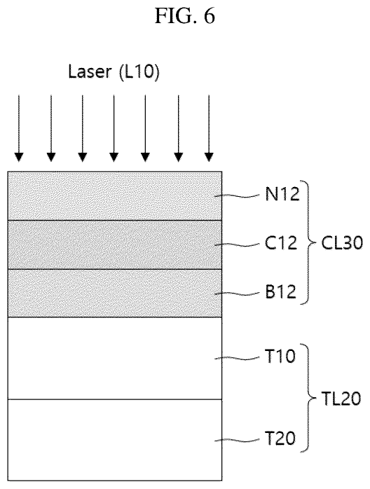

FIGS. 4 to 6 are cross-sectional views for explaining a laser heat treatment method according to another embodiment of the present invention. FIG. 4 is an embodiment modified based on FIG. 1B, FIG. 5 is an embodiment modified based on FIG. 2B, and FIG. 6 is an embodiment modified based on FIG. 3B.

Referring to FIGS. 4 to 6, the target substance layer TL20 may have a multi-layer structure including at least two different substance layers. The target substance layer TL20 may include a first substance layer T10 and a second substance layer T20. The first substance layer T10 may be disposed between the capping substance layers CL10, CL20, CL30 and the second substance layer T20. The first substance layer T10 may be in contact with the capping substance layers CL10, CL20, CL30, and the second substance layer T20 may be spaced apart from the capping substance layers CL10, CL20, CL30. The first substance layer T10 may be referred to as a ‘first target substance layer’, and the second substance layer T20 may be referred to as a ‘second target substance layer’.

The target substance layer TL20 may include at least any one of a semiconductor layer and an insulator layer, and the laser heat treatment may be performed to change the crystallinity, physical properties, or film quality of at least any one of the semiconductor layer and the insulator layer. Either of the first and the second substance layers (T10, T20) may be a semiconductor layer or an insulator layer. Furthermore, the target substance layer TL20 may be configured to include a conductive layer. Heat treatment may be performed on the first and the second substance layers T10, T20 constituting the target substance layer TL20. The layer whose physical properties are actually to be effectively changed through the heat treatment may be one or more layers among the first and second substance layers T10, T20.

Additionally, in the embodiments of FIG. 1A, FIG. 1B and FIG. 4, a non-conductive substance layer N12 as described in FIG. 2A and FIG. 2B may be additionally formed on the conductive substance layer C11. That is, in the embodiments of FIG. 1A, FIG. 1B and FIG. 4, the capping substance layer CL10 may further include a non-conductive substance layer N12 disposed on the conductive substance layer C11. In this case, the non-conductive substance layer N12 may effectively prevent heat in the conductive substance layer C11 generated by the laser from being emitted into the free space above the non-conductive substance layer N12. Therefore, during laser heat treatment, the speed at which heat is cooled through radiation (thermal radiation), convection (thermal convection), and conduction (thermal conduction) to the upper part of the capping substance layer may be reduced by the non-conductive substance layer N12. Furthermore, the non-conductive substance layer N12 may play a role to minimize changes in the conductive substance layer C11.

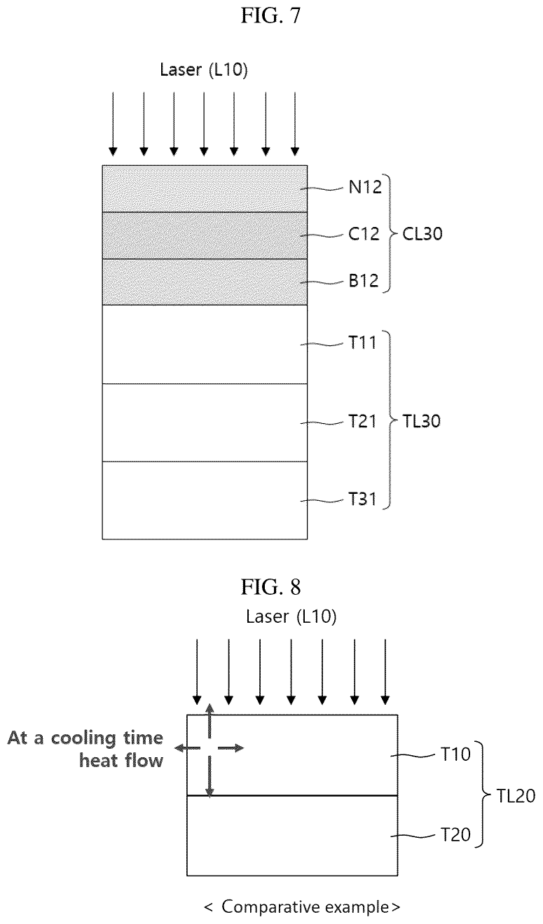

FIG. 7 is a cross-sectional view for explaining a laser heat treatment method according to another embodiment of the present invention. FIG. 7 is a modified embodiment of FIG. 3B.

Referring to FIG. 7, the target substance layer TL30 may have a multi-layer structure including at least three different substance layers. The target substance layer TL30 may include a first substance layer T11, a second substance layer T21, and a third substance layer T31. The first substance layer T11, the second substance layer T21, and the third substance layer T31 may be sequentially arranged downward from the capping substance layer CL30. The first substance layer T11 may be disposed between the capping substance layer CL30 and the second substance layer T21, and the second substance layer T21 may be disposed between the first substance layer T11 and the third substance layer T31. The first substance layer T11 may be referred to as a ‘first target substance layer,’ the second substance layer T21 may be referred to as a ‘second target substance layer,’ and the third substance layer T31 may be referred to as a ‘third target substance layer.’

The target substance layer TL30 may include at least any one of a semiconductor layer and an insulator layer, and the laser heat treatment may be performed to change the crystallinity, physical properties, or film quality of at least any one of the semiconductor layer and the insulator layer. At least any one of the first to the third substance layers T11, T21, T31 may be a semiconductor layer or an insulator layer. Furthermore, the target substance layer TL30 may be configured to include a conductive layer. Heat treatment may be performed on the first to the third substance layers T11, T21, T31 constituting the target substance layer TL30. The layer whose physical properties are actually to be effectively changed through the heat treatment may be one layer or more than one layer among the first to the third substance layers T11, T21, T31.

The target substance layer TL30 as shown in FIG. 7 may also be applied to the embodiments of FIG. 1B and FIG. 2B. Furthermore, the target substance layer may have a multi-layer structure of four or more layers.

Additionally, in the embodiments described with reference to FIG. 1A to FIG. 7, the capping substance layer CL10, CL20, CL30 may include two or more conductive substance layers C11 or C12. Furthermore, in the embodiments, the capping substance layer CL10, CL20, CL30 may include two or more non-conductive substance layers N11 or N12.

FIG. 8 is a cross-sectional view for explaining a laser heat treatment method according to a comparative example.

Referring to FIG. 8, in the case of a comparative example, heat treatment may be performed on the target substance layer TL20 by irradiating the target substance layer TL20 with a laser L10. In this case, the target substance layer TL20 may not be easily heated due to the absence of a heating layer which absorbs the laser L10 well. Furthermore, when the target substance layer TL20 is cooled after being heated, a problem may occur that heat distribution within the target substance layer TL20 becomes uneven as cooling (cooling through radiation, convection, and conduction) occurs relatively quickly to the upper free space of the target substance layer TL20. The arrows (red arrows) shown in the target substance layer TL20 in FIG. 8 schematically illustrate the heat flow when cooling occurs after heat treatment. Heat transfer may not occur sufficiently within the target substance layer TL20 in the lateral direction, and uneven heat distribution and the problems due to the uneven heat distribution may occur.

Although not illustrated, even if the laser heat treatment is performed after only the conductive substance layer which acts as the heating layer is formed on the target substance layer TL20 of FIG. 8, the above-mentioned heat distribution unevenness and problems resulting therefrom may occur.

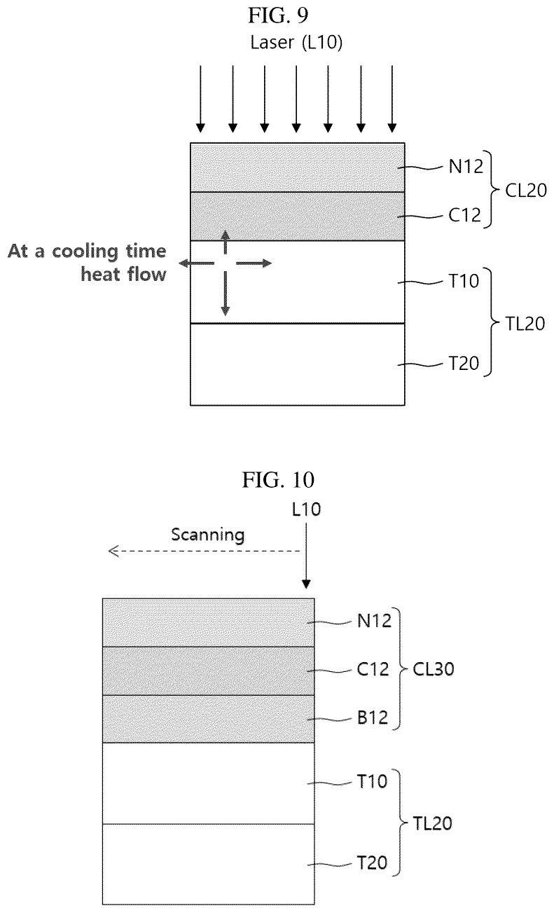

FIG. 9 is a cross-sectional view for explaining heat flow characteristics which may appear in a laser heat treatment method according to an embodiment of the present invention.

Referring to FIG. 9, while a capping substance layer CL20 having a multi-layer structure including a conductive substance layer C12 and a non-conductive substance layer N12 is formed on a target substance layer TL20, heat treatment may be performed on the target substance layer TL20 by irradiating a laser L10 to the capping substance layer CL20. In this case, the non-conductive substance layer N12 may effectively prevent the heat in the conductive substance layer C12 generated by the laser L10 from being emitted into the free space above the non-conductive substance layer N12. Therefore, during laser heat treatment, the speed at which the heat is cooled through radiation (thermal radiation), convection (thermal convection), and conduction (thermal conduction) to the upper part of the capping substance layer CL20 may be reduced by the non-conductive substance layer N12. In this regard, during laser heat treatment, heat transfer may be more effectively achieved in a lateral direction of the conductive substance layer C12, and a problem such as heat distribution imbalance between the conductive substance layer C12 and the target substance layer TL20 may be solved. The arrow (a red arrow) shown in the target substance layer TL20 in FIG. 9 schematically illustrates the heat flow when cooling after heat treatment.

At least a portion of the target substance layer TL20 may be patterned in a predetermined shape. Alternatively, the target substance layer TL20 may have different densities (layer densities) or different thicknesses depending on the region. In this case, heat absorption characteristics, heat reflection characteristics, etc. generated in the target substance layer TL20 may be different depending on the region. A problem such as imbalanced heat distribution within the target substance layer TL20 and the conductive substance layer C12 may occur due to this phenomenon. However, when a non-conductive substance layer N12 is arranged on a conductive substance layer C12, the non-conductive substance layer N12 prevents heat from being released to the upper portion of the capping substance layer CL20, thereby reducing the cooling rate and increasing the uniformity of heat. Therefore, the problem such as heat distribution imbalance between the conductive substance layer C12 and the target substance layer TL10 may be effectively prevented.

When performing laser heat treatment on non-conductive substances or semiconductor substances, the efficiency may be low even when energy higher than the bandgap is secured or energy higher than the bandgap is irradiated. In order to overcome this problem, according to an embodiment of the present invention, the heat treatment may be performed after a heating layer (a conductive substance layer) having a high laser absorption rate is formed on top of a target substance layer (a non-limiting example, a ceramic substance layer) having a low laser absorption rate in a heat treatment process using a laser. Through this process, a temperature of the target substance may be easily increased even with low energy, and unwanted structural changes and property deterioration which may occur in the substrate structure may be minimized when a physical transformation of the deposition substance occurs at a high temperature, and the target substance undergoes changes at a temperature below that. The conductive substance applied to the heating layer during laser heat treatment enables temperature increase with low laser energy through effective absorption of the laser, and may increase a temperature of the surrounding substance to be heat treated through conduction. Therefore, the laser energy for temperature increase may be lowered, and when the substance placed on top has a smaller physical change (non-limiting examples such as melting or thermal expansion) at a higher temperature than that of the substance on the bottom, the change in the structure due to the physical change on the bottom may be minimized. Furthermore, when a non-conductive substance layer is deposited on a conductive substance layer acting as a heating layer, the non-conductive substance layer may also play a role to prevent oxidation of the conductive substance layer (heating layer).

FIG. 10 is a cross-sectional view for explaining a laser heat treatment method according to an embodiment of the present invention.

Referring to FIG. 10, a laser L10 may be irradiated to the capping substance layer CL30 to perform heat treatment on the target substance layer TL20 after forming a capping substance layer CL30 on a substrate structure including a target substance layer TL20. The target substance layer TL20 and the capping substance layer CL30 may have configurations according to various embodiments described with reference to FIGS. 1A to 7. Here, as an example, a case in which the target substance layer TL20 and the capping substance layer CL30 have the configuration of FIG. 6 is illustrated.

The laser L10 may be irradiated to the capping substance layer CL30 in a scanning manner. The position of the laser L10 irradiated on the substrate structure may be moved, the position of the substrate structure may be moved with respect to the laser L10, or both the positions of the substrate structure and the laser L10 may be moved. In this way, when irradiating the laser L10 in a scanning manner, the heating process using the laser L10 may be performed more easily and at a faster speed. Therefore, the effect to reduce the process cost and process time may be obtained. However, when irradiating the laser, a stepper method may be used instead of the scanning method. That is, the laser may be irradiated to the capping substance layer in a stepper method.

In an embodiment of the present invention, when the laser L10 is irradiated in a scanning manner, the laser L10 may be irradiated by using a polygon scanner or a galvanometer scanner as a non-limiting example.

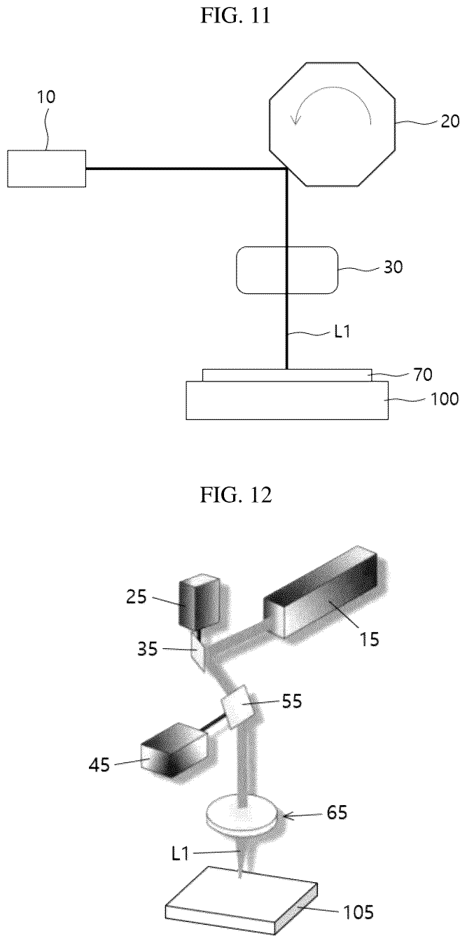

FIG. 11 is a drawing schematically illustrating a polygon scanner which may be applied to a laser heat treatment method according to an embodiment of the present invention.

Referring to FIG. 11, the polygon scanner may include a laser generator 10, a polygon mirror 20, and an optical system 30. A laser (laser beam) L1 generated from the laser generator 10 may be irradiated onto a substrate structure 70 via the polygon mirror 20 and the optical system 30. Here, the substrate structure 70 may include a target substance layer and a capping substance layer. The substrate structure 70 may be placed on a predetermined stage 100. As the polygon mirror 20 rotates, scanning of the laser L1 may be performed. If necessary, the position of the stage 100 may be moved. However, the configuration of the polygon scanner described with reference to FIG. 11 is merely exemplary, and it may be modified in various ways.

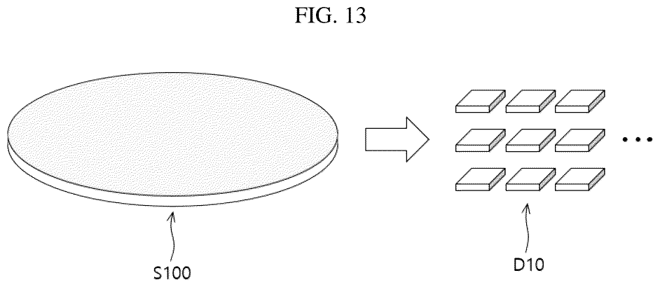

FIG. 12 is a drawing schematically illustrating a galvanometer scanner which may be applied to a laser heat treatment method according to an embodiment of the present invention.

Referring to FIG. 11, a galvanometer scanner may include a laser generator 15, a first driving unit 25, a first mirror 35, a second driving unit 45, a second mirror 55, and an optical system 65. The first mirror 35 is connected to the first driving unit 25 and may be rotated by the first driving unit 25. The first mirror 35 may be rotated about the first axis. The second mirror 55 is connected to the second driving unit 45 and may be rotated by the second driving unit 45. The second mirror 55 may rotate about a second axis. The second axis may be perpendicular to the first axis. The first driving unit 25 may include a first motor, and the second driving unit 45 may include a second motor. The first driving unit 25 may be a first galvanometer, and the second driving unit 45 may be a second galvanometer. A laser (laser beam) L1 generated from a laser generator 15 may be irradiated onto a substrate structure (not shown) via a first mirror 35, a second mirror 55, and an optical system 65. Here, the substrate structure may include a target substance layer and a capping substance layer. The substrate structure may be placed on a stage 105. As the first mirror 35 and the second mirror 55 rotate, scanning of the laser L1 may be performed. If necessary, the position of the stage 105 may be moved. However, the configuration of the galvanometer scanner described with reference to FIG. 12 is merely exemplary and may be modified in various ways.

In one embodiment of the present invention, the scanning speed of the laser may be about 1 m/s or more. According to an example, the scanning speed of the laser may be about 1 m/s to tens of km/s. However, the upper limit of the scanning speed of the laser is not limited to tens of km/s.

A manufacturing method of an electronic device (semiconductor device) according to an embodiment of the present invention may include a step for heat-treating a target substance layer by using a laser heat treatment method according to the embodiments described above, and a step of forming an electronic device (semiconductor device) including the heat-treated target substance layer. The above target substance layer may be arranged within a substrate structure. Accordingly, the manufacturing method of the electronic device (a semiconductor device) may include a step for heat-treating the substrate structure by using a laser heat treatment method according to the embodiments, and a step of forming an electronic device (a semiconductor device) from the heat-treated substrate structure. The step for forming the electronic device (a semiconductor device) from the above-described heat-treated substrate structure may include, for example, a step for performing a finishing process on the substrate structure, a step for dicing the substrate structure to form a plurality of elements, and a step for packaging the plurality of elements. Since the above-described finishing process, the dicing process, the packaging process, and the like may be same as the well-known processes, a detailed description thereof will be omitted.

FIG. 13 is a perspective view for explaining a manufacturing method of an electronic device using a laser heat treatment method according to an embodiment of the present invention.

Referring to FIG. 13, a plurality of elements D10 may be formed from a heat-treated substrate structure S100. The heat-treated substrate structure S100 may include a heat-treated target substance layer. The plurality of elements D10 may be electronic elements (semiconductor elements). The elements D10 may be memory elements or non-memory elements.

According to the embodiments of the present invention described above, a laser heat treatment method may be implemented in which heat distribution and heat transfer characteristics may be easily controlled and cooling behavior and cooling speed may be easily adjusted when performing heat treatment on a predetermined target object by using a laser. Furthermore, according to embodiments of the present invention, when performing a heat treatment on a predetermined target object by using a laser, it is possible to implement a laser heat treatment method which may preventing the problems such as characteristic changes/deterioration and substance damage/consumption due to unwanted reactions between substances while securing excellent heat treatment characteristics. When applying the laser heat treatment method according to embodiments of the present invention, it is possible to manufacture electronic devices (semiconductor devices) having excellent performance and uniformity, and to reduce the defect rate and improve the yield.

In the present specification, the preferred embodiments of the present invention have been disclosed, and although specific terms are used, these are only used in a general sense to easily describe the technological contents of the present invention and to help the understanding of the present invention, and are not used to limit the scope of the present invention. It will be apparent to those of ordinary skill in the art to which the present invention pertains that other modifications based on the technological spirit of the present invention may be implemented. Furthermore to the embodiments disclosed herein. It will be appreciated to those of ordinary skill in the art that a laser heat treatment method according to the embodiments described with reference to FIGS. 1A to 7 and FIGS. 9 to 13 and a manufacturing method of an electronic devices using the same may be variously substituted, changed and modified without departing from the spirit of the present invention. Therefore, the scope of the invention should not be determined by the described embodiments, but should be determined by the technological concepts described in the claims.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims. The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A laser heat treatment method comprising:
providing a substrate structure including a target substance layer to be heat treated;
forming a capping substance layer having a multi-layer structure including a non-conductive substance layer and a conductive substance layer on the target substance layer; and
performing heat treatment on the target substance layer by irradiating a laser to the capping substance layer.

2. The laser heat treatment method of the claim 1, wherein the non-conductive substance layer and the conductive substance layer are sequentially arranged on the target substance layer.

3. The laser heat treatment method of the claim 1, wherein the conductive substance layer and the non-conductive substance layer are sequentially arranged on the target substance layer.

4. The laser heat treatment method of the claim 3, wherein the capping substance layer further includes a reaction-suppressing layer disposed between the target substance layer and the conductive substance layer, and the reaction-suppressing layer is configured to suppress substance diffusion and reaction between the target substance layer and the conductive substance layer.

5. The laser heat treatment method of the claim 4, wherein the reaction suppression layer includes a non-conductive substance.

6. The laser heat treatment method of the claim 4, wherein the reaction suppression layer has a thickness of 0.5˜1000 nm.

7. The laser heat treatment method of the claim 1, wherein the non-conductive substance layer includes an inorganic dielectric substance.

8. The laser heat treatment method of the claim 2, wherein the non-conductive substance layer has a thickness in the range of about 0.5 to 1000 nm.

9. The laser heat treatment method of the claim 3, wherein the non-conductive substance layer may have a thickness in the range of about 0.5 to 1000 nm.

10. The laser heat treatment method of the claim 1, wherein the conductive substance layer may include a metallic substance.

11. The laser heat treatment method of the claim 1, wherein the conductive substance layer may have a thickness in a range of about 0.5 to 1000 nm.

12. The laser heat treatment method of the claim 1, wherein the target substance layer has a single-layer structure or a multi-layer structure including at least two different substance layers.

13. The laser heat treatment method of the claim 1, wherein the target substance layer includes at least any one of a semiconductor layer and an insulator layer, and the laser heat treatment is performed to change crystallinity, physical properties, or film quality of at least any one of the semiconductor layer and the insulator layer.

14. The laser heat treatment method of the claim 1, further including removing at least a portion of the capping substance layer after the step for performing heat treatment on the target substance layer.

15. The laser heat treatment method of the claim 1, wherein the laser is irradiated to the capping substance layer in a scanning manner.

16. The laser heat treatment method of the claim 15, wherein the laser is irradiated by using a polygon scanner or a galvanometer scanner.

17. The laser heat treatment method of the claim 15, wherein the scanning speed of the above laser is 1 m/s or more.

18. The laser heat treatment method of the claim 1, wherein the laser is irradiated to the capping substance layer in a stepper manner.

19. The laser heat treatment method of the claim 1, wherein the laser has a wavelength of about 0.01 μm to 11 μm.

20. A manufacturing method of an electronic device comprising:
performing heat treatment on a target substance layer by using the laser heat treatment method described in claim 1; and
forming an electronic device including the heat-treated target substance layer
